(19) United States
(12) Patent Application Publication
(10) Pub. No.: US 2013/0128654 A1
(43) Pub. Date: May 23, 2013

(54) NONVOLATILE MEMORY ELEMENT, METHOD OF MANUFACTURING NONVOLATILE MEMORY ELEMENT, METHOD OF INITIAL BREAKDOWN OF NONVOLATILE MEMORY ELEMENT, AND NONVOLATILE MEMORY DEVICE

(71) Applicants: Shinichi Yoneda, Kyoto (JP); Yukio Hayakawa, Kyoto (JP); Kiyotaka Tsuji, Osaka (JP)

(72) Inventors: Shinichi Yoneda, Kyoto (JP); Yukio Hayakawa, Kyoto (JP); Kiyotaka Tsuji, Osaka (JP)

(21) Appl. No.: 13/814,557

(22) PCT Filed: Jun. 7, 2012
(86) PCT No.: PCT/JP2012/003737

§ 371 Date: Feb. 6, 2013

(30) Foreign Application Priority Data
Jun. 10, 2011 (JP) 2011-130474

(51) Int. Cl. G11C 13/00; H01L 45/00

(52) U.S. Cl. CPC G11C 13/0033; H01L 45/145; H01L 45/04
USPC 365/148; 257/1; 438/382

(57) ABSTRACT

A nonvolatile memory element includes a current steering element which bidirectionally rectifies current in response to applied voltage and a variable resistance element connected in series with the current steering element. The current steering element includes an MSM diode and an MSM diode which are connected in series and each of which bidirectionally rectifies current in response to applied voltage. The MSM diode and the MSM diode include a lower electrode, a first current steering layer, a first metal layer, a second current steering layer, and an upper electrode which are stacked in this order. The current steering element has a breakdown current which is larger than an initial breakdown current which flows in the variable resistance element at the time of initial breakdown.

### TECHNICAL FIELD

The present invention relates to a nonvolatile memory element including a current steering element which bidirectionally rectifies current in response to applied voltage, a method of manufacturing the nonvolatile memory element, a method of initial breakdown of the nonvolatile memory element, and a nonvolatile memory device.

### BACKGROUND ART

In recent years, mobile digital appliances such as small and thin digital AV players and digital cameras have become increasingly sophisticated. Along with this, there has been an increasing demand for large-capacity and high-speed memory devices for use in such appliances. As memory devices that meet the demand, memory devices including a ferroelectric capacitor or a variable resistance layer are drawing attention.

The memory devices including a variable resistance layer can be classified into a write-once type and a rewritable type. Variable resistance elements of the rewritable type can be further classified into two types. One is generally called unipolar (or monopolar) variable resistance elements, which are variable resistance elements having a characteristic of changing from a high resistance state to a low resistance state and from the low resistance state to the high resistance state in response to two threshold voltages of the same polarity. Another is generally called bipolar variable resistance elements, which are variable resistance elements having a characteristic of changing from a high resistance state to a low resistance stale and from the low resistance state to the high resistance state in response to two threshold voltages of different polarities.

In the memory devices in which such variable resistance elements each including a variable resistance layer are arranged in an array, it is common to connect each variable resistance element in series with a current steering element such as a transistor or a rectifying element. This prevents sneak current from causing write disturb, crosstalk between adjacent memory cells, and so on, and thus, the memory device can reliably perform its memory operation.

In general, it is possible to control the resistance change of the unipolar variable resistance element using two different voltages of the same polarity. Thus, when a diode is to be used as the current steering element, a unidirectional diode can be used. This provides the possibility of simplifying the structure of the memory cell including the variable resistance element and the current steering element. The unidirectional diode here refers to a diode having a nonlinear on-off characteristic for one voltage polarity. However, the unipolar variable resistance element requires reset pulses with a large pulse width at the time of reset (at the time of changing to the high resistance state), resulting in a slow operation speed.

In contrast, the resistance change of the bipolar variable resistance element is controlled using two threshold voltages of different polarities. Thus, when a diode is to be used as the current steering element, a bidirectional diode is required. The bidirectional diode here refers to a diode having a nonlinear on-off characteristic for both voltage polarities. With the bipolar variable resistance element, pulses with a short pulse width can be used for both setting and resetting, allowing a high-speed operation.

In the past, cross-point memory devices as disclosed in Patent Literature (PTL) 1 have been proposed which include memory cells each formed by connecting the variable resistance element in series with, as the current steering element, a unidirectional rectifying element such as a p-n junction diode or a schottky diode.

Cross-point memory devices as disclosed in PTL 2 have also been proposed which include memory cells each formed by connecting the variable resistance element in series with, as the current steering element, a diode having a bidirectional rectification property.

### CITATION LIST

### Patent Literature

[PTL 1]
Japanese Unexamined Patent Application Publication No. 2006-140489
[PTL 2]
Japanese Unexamined Patent Application Publication No. 2006-203098

### SUMMARY OF INVENTION

### Technical Problem

The nonvolatile memory element including such a variable resistance element and a current steering element is demanded to have higher stability.

It is thus an object of the present invention to provide a nonvolatile memory element having high stability.

### Solution to Problem

To solve the above problems, a nonvolatile memory element according to an aspect of the present invention is a nonvolatile memory element including: a current steering element which bidirectionally rectifies current in response to applied voltage; and a variable resistance element which is connected in series with the current steering element and reversibly changes between a high resistance state and a low resistance state according to a polarity of applied voltage, wherein the current steering element includes a first bidirectional diode and a second bidirectional diode which are connected in series and each of which bidirectionally rectifies current in response to applied voltage, the first bidirectional diode and the second bidirectional diode include a first electrode, a first current steering layer, a first metal layer, a second current steering layer, and a second electrode which are stacked in this order, and the current steering element has a breakdown current which is larger than or equal to an initial breakdown current which flows in the variable resistance element at the time of initial breakdown which changes the variable resistance element from an initial state to a state in which the variable resistance element can reversibly change between the high resistance state and the low resistance state, the initial state being a state of the variable resistance element after being manufactured.

### Advantageous Effects of Invention

With this, a nonvolatile memory element having high stability can be provided.

### BRIEF DESCRIPTION OF DRAWINGS

FIG. 1A is a cross-section diagram of a current steering element according to Embodiment 1 of the present invention.

FIG. 1B is a diagram showing an equivalent circuit of a current steering element according to Embodiment 1 of the present invention.

FIG. 2 is a diagram showing the current-voltage characteristic of a current steering element according to Embodiment 1 of the present invention.

FIG. 3 is a diagram showing the current-voltage characteristic of a current steering element according to Embodiment 1 of the present invention.

FIG. 4 is a diagram showing the current-voltage characteristic of a current steering element according to Embodiment 1 of the present invention.

FIG. 5A is a cross-section diagram of a current steering element according to Embodiment 2 of the present invention.

FIG. 5B is a diagram showing an equivalent circuit of a current steering element according to Embodiment 2 of the present invention.

FIG. 6 is a diagram showing the current-voltage characteristic of a current steering element according to Embodiment 2 of the present invention.

FIG. 7A is a cross-section diagram of a nonvolatile memory element according to Embodiment 3 of the present invention.

FIG. 7B is a diagram showing an equivalent circuit of a nonvolatile memory element according to Embodiment 3 of the present invention.

FIG. 8 is a diagram showing the resistance change characteristic of a nonvolatile memory element according to Embodiment 3 of the present invention, relative to the number of pulses.

FIG. 9A is a block diagram showing a structure of a nonvolatile memory device according to Embodiment 4 of the present invention.

FIG. 9B is a circuit diagram of a memory cell according to Embodiment 4 of the present invention.

FIG. 9C is a cross-section diagram of a memory cell according to Embodiment 4 of the present invention.

FIG. 10 is a diagram showing the current-voltage characteristic of bidirectional diodes.

FIG. 11A is a cross-section diagram showing a basic structure of an MSM diode.

FIG. 11B is a diagram showing an equivalent circuit of an MSM diode

FIG. 12 is a diagram showing the basic, current-voltage characteristics of MSM diodes.

### DESCRIPTION OF EMBODIMENTS

### Embodiment 1

### (Underlying Knowledge Forming Basis of the Present Invention)

Well-known bidirectional (bipolar) diodes include, for example, varistors as disclosed in PTL 2, metal-insulator-metal (MIM) diodes, and metal-semiconductor-metal (MSM) diodes.

Forming a memory cell by connecting such a diode having a bidirectional rectification property (hereinafter, such a diode is also referred to as “bidirectional diode”) to the variable resistance layer in series provides a memory device which performs a bipolar operation with the bidirectional rectification property.

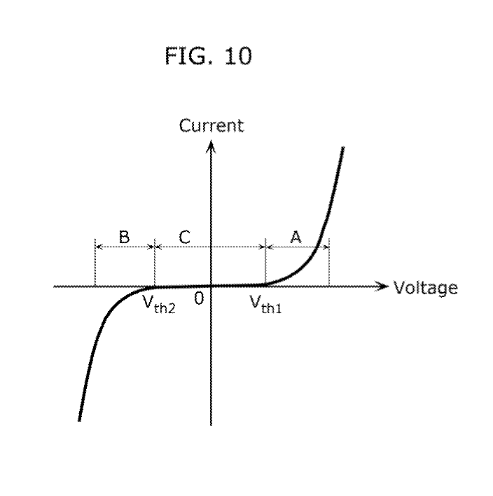

FIG. 10 is a diagram showing the voltage-current characteristic of well-known bidirectional diodes. Using FIG. 10, the following describes the characteristics of the bidirectional diodes and the performance required of the bidirectional diodes.

The bidirectional diodes such as the MIM diodes, the MSM diodes, and the varistors exhibit a nonlinear current resistance characteristic. Optimization of the electrode materials and the materials interposed between the electrodes allows the voltage-current characteristic of the bidirectional diodes to be substantially symmetric to the polarity of applied voltage. More specifically, it is possible to provide such a characteristic that current variation in response to positive applied voltage and current variation in response to negative applied voltage have substantial point symmetry with respect to the origin point 0.

Furthermore, these bidirectional diodes have very high current resistance in a range (range C in FIG. 10) in which the applied voltage is equal to or less than a first critical voltage Vth1. (lower limit voltage of a range A in FIG. 10) and equal to or greater than a second critical voltage Vth2 (upper limit voltage of a range B in FIG. 10). The current resistance rapidly decreases when the applied voltage exceeds the first critical voltage Vth1 or falls below the second critical voltage Vth2. This means that these two-terminal elements have such a nonlinear current resistance characteristic that allows large current to flow when the applied voltage exceeds the first critical voltage or falls below the second critical voltage.

Thus, combining these bidirectional diodes with bipolar memory elements, that is, using the bidirectional diodes as the current steering elements, provides a cross-point memory device including bipolar variable resistance elements.

The variable resistance memory device has an electrical resistance value which is changed upon application of electrical pulses on the variable resistance element. This causes the state of the variable resistance element of the memory device to change to the high resistance state or the low resistance state. To do so, it is usually necessary to pass relatively large current through the variable resistance element. Hereinafter, the current necessary to change the state of the variable resistance element from the high resistance state to the low resistance state (or vice versa) is called resistance change current.

When the variable resistance layer includes a high concentration layer (high resistance layer) and a low concentration layer (low resistance layer) which are stacked, the resistance value of the variable resistance element in the initial state immediately after being manufactured is higher than the resistance value of the variable resistance element in the high resistance state in the normal operation. Furthermore, the resistance change operation cannot be performed even when an electrical signal (electrical pulses) used in the normal operation is applied to the variable resistance element in the initial state, thereby failing to obtain a desired resistance change characteristic.

To overcome this and obtain a desired resistance change characteristic, initial breakdown is performed, so that the variable resistance element changes from the initial state to a state in which the variable resistance element can reversibly change between the high resistance state and the low resistance state. More specifically, application of high-voltage electrical pulses on the variable resistance element in the initial state forms an electrical filament path in the high resistance layer (breakdown occurs in the high resistance layer). The voltage of the electrical pulses applied for the initial breakdown (initial breakdown voltage) is higher than the voltage of the electrical pulses necessary for changing the variable resistance element from the high resistance state to the low resistance state or from the low resistance state to the high resistance state. The current which flows in the variable resistance element at the initial breakdown is called initial breakdown current.

For example, a memory device is disclosed in PTL 2 which passes a current having a density equal to or greater than 30000 A/cm² (write current of approximately 200 μA when the electrode area is 0.8 μm×0.8 μm) through a bidirectional diode which is a varistor, to write data in the variable resistance element.

Thus, with the memory device formed by connecting the variable resistance layer and the bidirectional diode in series, first, the relationship is important between (i) the maximum current which the bidirectional diode can allow to pass (breakdown current) and (ii) the resistance change current and the initial breakdown current.

A breakdown current of the bidirectional diode below the resistance change current causes breakdown of the rectifying element before a resistance change can take place. This results in insulation or a short circuit.

Normally, the resistance change operation needs to be performed with a current smaller than the breakdown current of the bidirectional diode to prevent such malfunctions caused by the breakdown, The current which flows in the bidirectional diode in the normal operation (resistance change operation) is called ON current of the bidirectional diode. It is sufficient as long as each of the above currents satisfies the relationship below in each bit.

“Breakdown current of the bidirectional diode”>“ON current of the bidirectional diode”≧“Resistance change current”

The larger the above differences are, the larger the operation margin of the element is, thereby increasing the operation reliability of the bidirectional diode and the memory device.

With the cross-point memory device, it is necessary to reduce, using the bidirectional diode, leak current flowing into unselected memory cells.

More specifically, to perform a write and read operation of a selected memory cell, it is necessary to use the ON state of the bidirectional diode in the range A or B shown in FIG. 10 and, at the same time, reduce the leak current (OFF current) flowing in the unselected memory cells, in the OFF region represented by the range C. Here, insufficient reduction of the OFF current causes a change in the resistance of the variable resistance layers of the unselected memory cells. This leads to a problem of failing to properly perform the write or read operation of the selected memory cell.

The memory device disclosed in PTL 1 is unipolar, having no bidirectional rectification property.

With the unipolar variable resistance element, a change from the low resistance state to the high resistance state (i.e., resetting) requires electrical pulses with a pulse width (1 μsec or less) larger than that required for setting.

In contrast, with the bipolar variable resistance element, the resistance change is possible using electrical pulses with a small pulse width (e.g., 500 nsec or less) for both setting and resetting. This shows that the bipolar variable resistance element is superior to the unipolar variable resistance element in writing speed.

This indicates a problem that the bipolar variable resistance element that is superior in writing speed cannot be used in the memory device disclosed in PTL 1.

PTL 2 discloses that the memory device of PTL 2 passes a current having a density equal to or greater than 30000 A/cm² (write current of approximately 200 μA when the electrode area is 0.8 μm×0.8 μm) to write data in the variable resistance element using a varistor. However, PTL 2 does not mention the relationship between the breakdown current of the rectifying element and the operating current. Therefore, it is unclear as to how large the margin is in relation to the actual operation of the element. Furthermore, PTL 2 does not explicitly disclose a solution for the case where a resistance change current several times larger than 30000 A/cm², or greater is required.

Moreover, since the varistor gains the rectification property from the characteristics of the crystal grain boundary of the material interposed between the electrodes, there is also a problem that use of the varistor in a multilayer memory or the like which includes stacked layers is likely to cause non-uniformity in the characteristics of the current steering elements.

To overcome such problems, the inventors of the present invention have discovered that it is possible to use, as the current steering element which allows large current to pass, an MSM diode having a structure in which a SiNₓ current steering layer is interposed between electrodes.

Here, SiNₓ (0<×x≦0.85) refers to nitrogen-deficient silicon nitride. The value of x represents the level of nitriding (composition ratio). The electrical conduction property of SiNₓ significantly depends on the value of x. More specifically, SiNₓ is an insulator in terms of stoichiometric composition (x=1.33, i.e., Si₃N₄); however, SiNₓ gradually changes to behave as a semiconductor when the nitrogen ratio is reduced (i.e., when the value of x is reduced).

The MSM diode includes a semiconductor interposed between metal electrodes, and is expected to have a current supplying capability higher than that of the MIM diode. Furthermore, unlike the varistor, the MSM diode does not utilize the characteristics of the crystal grain boundary or the like, and is thus insusceptible to a heat history and so on during the manufacturing process. It is therefore expected that current steering elements having more uniformity can be provided using the MS diodes.

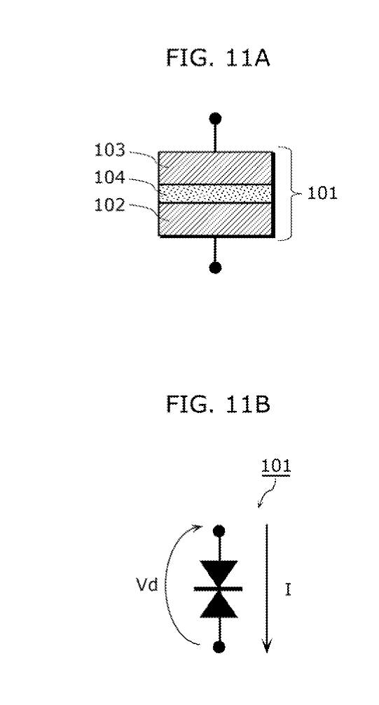

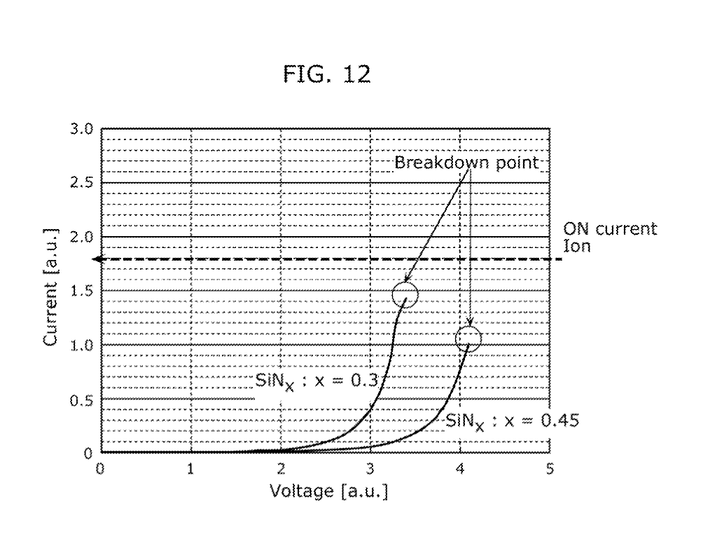

Using FIG. 11A, FIG. 11B, and FIG. 12, the following describes in detail problems of the above-described MSM diodes.

FIG. 11A is a cross-section diagram schematically showing a structure of an MSM diode 101. FIG. 11B is a diagram showing an equivalent circuit of the MSM diode 101.

The MSM diode 101 includes: a lower electrode 102 which is an example of a first electrode; an upper electrode 103 which is an example of a second electrode; and a current steering layer 104 interposed between the lower electrode 102 and the upper electrode 103. Here, each of the lower electrode 102 and the upper electrode 103 includes tantalum nitride including tantalum (Ta) and nitrogen (N). The current steering layer 104 includes silicon nitride including silicon (Si) and nitrogen (N).

The MSM diode 101 shown in FIG. 11A is manufactured in the following steps: First, as a conductive layer serving as the lower electrode 102, tantalum nitride having a thickness of 50 nm is formed on a substrate by reactive sputtering. Then, as the current steering layer 104, silicon nitride having a thickness of 20 nm is formed on the tantalum nitride by reactive sputtering. Then, as a conductive layer serving as the upper electrode 103, tantalum nitride having a thickness of 50 nm is formed on the silicon nitride by reactive sputtering. After that, ordinary photolithography and dry etching are applied. The area of each of the lower electrode 102 and the upper electrode 103 is 0.5 μm×0.5 μm.

The material including Si and N, that is, the material included in the current steering layer 104, refers to silicon nitride. The silicon nitride forms a tetrahedral amorphous semiconductor which forms a tetrahedral coordinate bond. The tetrahedral amorphous semiconductor basically has a structure similar to the structure of single-crystal silicon or germanium, and thus has a characteristic that a difference in structure attributable to introduction of an element other than Si is easily reflected in the physical properties. For this reason, the use of the silicon nitride for the current steering layer 104 facilitates control over the physical properties of the current steering layer 104 through control over the structure of the silicon nitride. Therefore, this produces an advantageous effect of facilitating control over a potential barrier formed between the lower electrode 102 and the upper electrode 103.

More specifically, the use of SiNₓ as the current steering layer 104 allows the band gap to be continuously changed through a change in the ratio of nitrogen in SiNₓ. This makes it possible to control the size of a potential barrier formed between (i) the lower electrode 102 and the upper electrode 103 and (ii) the current steering layer 104 that is adjacent to the lower electrode 102 and the upper electrode 103.

The lower electrode 102 and the upper electrode 103 may comprise a metal such as Al, Cu Ti, W, Ir, Cr, Ni, or Nb, or a mixture (alloy) of these metals.

Alternatively, the lower electrode 102 and the upper electrode 103 may comprise: a compound having a conductive property, such as TiN, TiW, TaN, TaSi₂, TaSiN, TiAlN, NbN, WN, WSi₂, WSiN, RuO₂, In₂O₃, SnO₂, or IrO₂; or a mixture of these compounds having a conductive property. Here, the materials comprised in the lower electrode 102 and the upper electrode 103 are not limited to these materials, and any materials may be used as long as a rectification property can be exhibited through the potential barrier formed between the current steering layer 104 and the lower and upper electrodes.

FIG. 12 shows the current-voltage characteristics of the MSM diodes 101 shown in FIG. 11A and FIG. 11B. Here, the current steering layer 104 of one of the MSM diodes 101 includes SiNₓ where x=0.3 and the current steering layer 104 of the other MSM diode 101 includes SiNₓ were x=0.45, and the SiNₓ thickness is 20 nm for both MSM diodes 101. The directions of applied voltage Vd and current I are shown in FIG. 11B. The voltage is applied in 20-mV increments.

As described earlier, when the value of x in SiNₓ increases and SiNₓ becomes closer to an insulator, current flows less easily. At the same time, the breakdown current decreases. The MSM diode including SiNₓ where x=0.3 has a higher breakdown current than the MSM diode including SiNₓ where x=0.45.

With the circuit of a typical memory device, the ON current of the above MSM diodes is required to be Ion. However, the MSM diode including SiNₓ where x=0.3 and the MSM diode including SiNₓ where x=0.45 both have the breakdown current below the required ON current Ion. This means that neither MSM diode can be used in the actual memory device.

This creates a need to use a variable resistance element having a resistance change current (i.e., ON current) as small as the breakdown current of the bidirectional diode or less.

However, this imposes a restriction on the composition, material, and so on of usable variable resistance elements, thereby significantly narrowing the options for the memory cell structure. This is a problem that the inventors of the present invention have found.

Furthermore, with the above MSM diodes, the potential barrier can be adjusted through a change in the composition SiNₓ (concentration of nitrogen), which produces an advantageous effect of facilitating the setting of the ON and OFF regions of the MSM diodes.

However, it is not possible to make use of this advantageous effect unless the breakdown current of the MSM diode is sufficiently large. For example, when the current which flows upon application of low voltage is small as in the case of the MSM diode including SiNₓ where x=0.45 shown in FIG. 12, it is virtually impossible to use the MSM diode which can have a wide OFF region. This is another problem that the inventors have found.

Moreover, the inventors have also found a problem that the breakdown current of the bidirectional diode being smaller than the initial breakdown current causes a breakdown of the bidirectional diode at the time of initial breakdown. In other words, the relationship of “Breakdown current of the bidirectional diode”>“Initial breakdown current” needs to be satisfied.

The present embodiment is directed at solving the above problems and provides: a current steering element which bidirectionally rectifies current in response to applied voltage and has a large breakdown current; and a nonvolatile memory element which includes the current steering element.

To solve the above problems, a nonvolatile memory element according to an aspect of the present invention is a nonvolatile memory element including: a current steering element which bidirectionally rectifies current in response to applied voltage; and a variable resistance element which is connected in series with the current steering element and reversibly changes between a high resistance state and a low resistance state according to a polarity of applied voltage, wherein the current steering element includes a first bidirectional diode and a second bidirectional diode which are connected in series and each of which bidirectionally rectifies current in response to applied voltage, the first bidirectional diode and the second bidirectional diode include a first electrode, a first current steering layer, a first metal layer, a second current steering layer, and a second electrode which are stacked in this order, and the current steering element has a breakdown current which is larger than an initial breakdown current which flows in the variable resistance element at a time of initial breakdown which changes the variable resistance element from an initial state to a state in which the variable resistance element can reversibly change between the high resistance state and the low resistance state, the initial state being a state of the variable resistance element after being manufactured.

This structure increases the breakdown current and voltage of the current steering element as compared to that of a current steering element which includes a single bidirectional diode including only one current steering layer. The breakdown current of the current steering element being larger than the initial breakdown current reduces the occurrence of breakdown of the current steering element at the time of initial breakdown.

At least one of the first current steering layer and the second current steering layer may be a semiconductor layer.

The semiconductor layer may comprise SiNₓ where 0<x≦0.85.

Furthermore, the semiconductor layer may comprise silicon.

At least one of the first current steering layer and the second current steering layer may be an insulator.

The current steering element may include first to Nth bidirectional diodes connected in series and including the first bidirectional diode and the second bidirectional diode, where N may be an integer greater than or equal to 3, the first to Nth bidirectional diodes may include: the first electrode; the second electrode; and a stacked structure which includes layers stacked between the first electrode and the second electrode, and the stacked structure may include first to Nth current steering layers and first to (N−1)th metal layers which are alternately stacked.

According to this structure, the current steering element according to an aspect of the present invention includes three or more bidirectional diodes connected in series. This further increases the breakdown current and voltage of the current steering element.

The variable resistance element may include: a third electrode; a fourth electrode; and an oxygen-deficient transition metal oxide layer interposed between the third electrode and the fourth electrode.

The transition metal oxide layer may include a first transition metal oxide layer and a second transition metal oxide layer which are stacked, the second transition metal oxide layer being different from the first transition metal oxide layer in degree of oxygen deficiency.

A nonvolatile memory device according to an aspect of the present invention is a nonvolatile memory device including: a memory cell array in which a plurality of the nonvolatile memory elements are two-dimensionally arranged; a selection circuit which selects at least one of the nonvolatile memory elements from the memory cell array; a write circuit which applies voltage on the nonvolatile memory element selected by the selection circuit, to change a variable resistance element included in the selected nonvolatile memory element from one of a high resistance state and a low resistance state to the other; and a sense amplifier which determines whether the variable resistance element included in the nonvolatile memory element selected by the selection circuit is in the high resistance state or the low resistance state.

It is to be noted that the present invention can be realized not only in the form of a nonvolatile memory element (memory cell) but also in the form of a nonvolatile memory device (memory device) which includes the nonvolatile memory element. Furthermore, the present invention can also be realized in the form of a method of manufacturing such a nonvolatile memory element or a method of manufacturing such a nonvolatile memory device. The present invention can further be realized in the form of a method of controlling such a nonvolatile memory element or a nonvolatile memory device or a method of initial breakdown of such a nonvolatile memory element.

For example, a method of manufacturing a nonvolatile memory element according to an aspect of the present invention is a method of manufacturing a nonvolatile memory element, including: forming a current steering element which bidirectionally rectifies current in response to applied voltage; and forming a variable resistance element which is connected in series with the current steering element and reversibly changes between a high resistance state and a low resistance state according to a polarity of applied voltage, wherein the forming of a current steering element includes: forming a first electrode on a semiconductor substrate; forming a first current steering layer on the first electrode; forming a first metal layer on the first current steering layer; forming a second current steering layer on the first metal layer; and forming a second electrode on the second current steering layer, the first electrode, the first current steering layer, the first metal layer, the second current steering layer, and the second electrode are included in a first bidirectional diode and a second bidirectional diode which are connected in series and each of which bidirectionally rectifies current in response to applied voltage, and the current steering element has a breakdown current which is larger than an initial breakdown current which flows in the variable resistance element at a time of initial breakdown which changes the variable resistance element from an initial state to a state in which the variable resistance element can reversibly change between the high resistance state and the low resistance state, the initial state being a state of the variable resistance element after being manufactured.

Furthermore, a method of initial breakdown of a nonvolatile memory element according to an aspect of the present invention is a method of initial breakdown of a nonvolatile memory element, the nonvolatile memory element including: a current steering element which bidirectionally rectifies current in response to applied voltage; and a variable resistance element which is connected in series with the current steering element and reversibly changes between a high resistance state and a low resistance state according to a polarity of applied voltage, the current steering element including a first bidirectional diode and a second bidirectional diode which are connected in series and each of which bidirectionally rectifies current in response to applied voltage, the first bidirectional diode and the second bidirectional diode including a first electrode, a first current steering layer, a first metal layer, a second current steering layer, and a second electrode which are stacked in this order, and the method of initial breakdown including performing initial breakdown to change the variable resistance element from an initial state to a state in which the variable resistance element can reversibly change between the high resistance state and the low resistance state, the initial state being a state of the variable resistance element after being manufactured, wherein the current steering element has a breakdown current which is larger than an initial breakdown current which flows in the variable resistance element at a time of the initial breakdown.

### Embodiment 1

Hereinafter, Embodiment 1 of a current steering element according to an aspect of the present invention will be described in detail using the drawings. The numerical values, shapes, materials, structural elements, the arrangement and connection of the structural elements, steps, the processing order of the steps etc., shown in the following embodiments are mere examples, and are therefore not intended to limit the present invention. Furthermore, among the structural elements in the following embodiments, structural elements not recited in any one of the independent claims representing the most generic concepts are described as arbitrary structural elements.

The current steering element according to Embodiment 1 of the present invention includes two bidirectional diodes connected in series. This increases the breakdown current of the current steering element according to Embodiment 1 of the present invention.

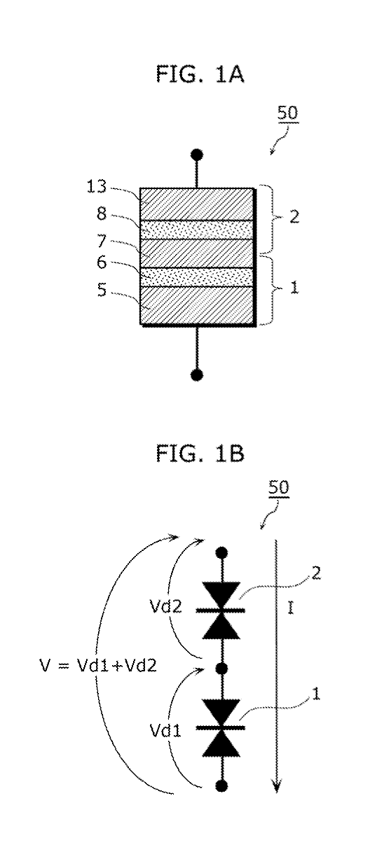

FIG. 1A is a cross-section diagram schematically showing a structure of a current steering element 50 according to Embodiment 1 of the present invention. FIG. 1B is a diagram showing an equivalent circuit of the current steering element 50.

The current steering element 50 is an element for steering current and is a bidirectional diode which bidirectionally rectifies current in response to applied voltage. The current steering element 50 includes an MSM diode 1 and an MSM diode 2 connected in series.

The MSM diode 1 corresponds to a first bidirectional diode according to an aspect of the present invention, and bidirectionally rectifies current in response to applied voltage. The MSM diode 2 corresponds to a second bidirectional diode according to an aspect of the present invention, and bidirectionally rectifies current in response to applied voltage. For example, the MSM diodes 1 and 2 have the current-voltage characteristic shown in FIG. 10.

The MSM diodes 1 and 2 include a lower electrode 5, a first current steering layer 6, a first metal layer 7, a second current steering layer 8, and an upper electrode 13 which are stacked in this order. More specifically, the MSM diode 1 includes the lower electrode 5, the first current steering layer 6, and the first metal layer 7. The MSM diode 2 includes the first metal layer 7, the second current steering layer 8, and the upper electrode 13. Here, the lower electrode 5 and the upper electrode 13 respectively correspond to a first electrode and a second electrode according to an aspect of the present invention.

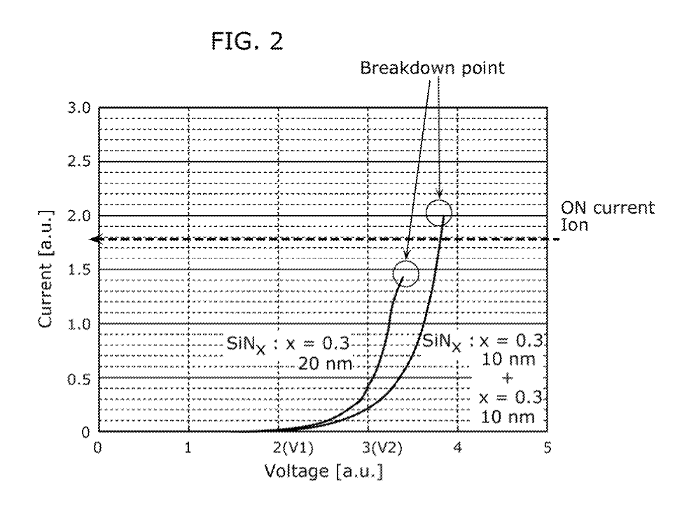

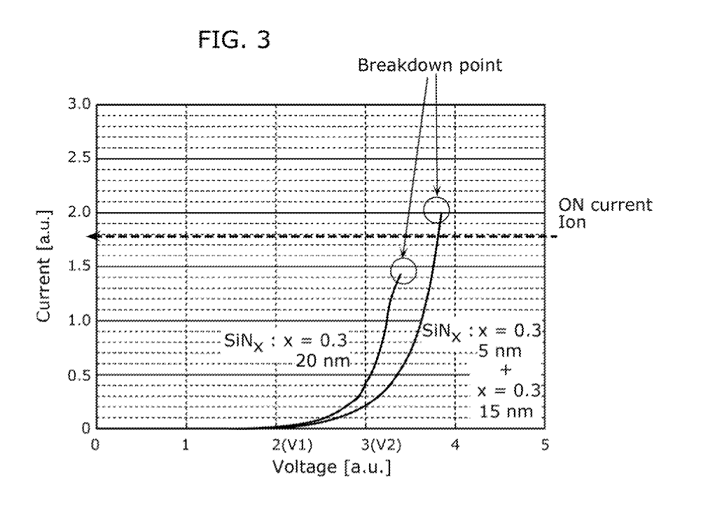

Using FIG. 2, the following describes a current-voltage characteristic which is a feature of the current steering element 50 according to an aspect of the present invention.

FIG. 2 is a diagram showing the current-voltage characteristic of a conventional current steering element which includes a single MSM diode and the current-voltage characteristic of the current steering element 50 according to Embodiment 1 of the present invention. Here, a current steering layer included in the conventional current steering element includes SiNₓ where x=0.3 and is 20 nm in thickness. Each of the first current steering layer 6 and the second current steering layer 8 included in the current steering element 50 according to Embodiment 1 of the present invention includes SiNₓ where x=0.3 and is 10 nm in thickness. The upper electrode and the lower electrode of the conventional current steering element and the current steering element according to Embodiment 1 are tantalum nitrides each having a thickness of 50 nm. Both the upper electrode and the lower electrode of the conventional current steering element and the current steering element according to Embodiment 1 have an area of 0.5 μm×0.5 μm.

It is to be noted that FIG. 2 shows curves which are drawn by plotting current values while gradually increasing the voltage applied to each current steering element from 0 V until the current steering element (more accurately, the MSM diode(s)) breaks down (i.e., until a breakdown point is reached).

As shown in FIG. 2, the breakdown current of the current steering element 50 according to Embodiment 1 of the present invention is significantly higher than that of the conventional current steering element. Moreover, it is apparent that the breakdown current is well above the ON current Ion required of the circuit.

It is to be noted that the total thickness of the two current steering layers included in the current steering element 50 according to Embodiment 1 of the present invention is 20 nm, which is the same as the thickness of the single current steering layer included in the conventional current steering element. Thus, the voltage (threshold voltage) which causes a steep increase in current in the conventional current steering element and the voltage (threshold voltage) which causes a steep increase in current in the current steering element 50 according to Embodiment 1 are substantially equal to each other at V1 as shown in FIG. 2.

The conventional current steering element and the current steering element 50 according to Embodiment 1 have different characteristics in the region greater than or equal to V2. However, this region is not used in the actual operation, and thus the influence of the difference in the characteristics in this region is small.

In such a manner, with the current steering element 50 according to Embodiment 1 of the present invention, it is possible to increase the breakdown current with no change to the characteristics, such as the threshold voltage, of the current steering element which includes a single MSM diode.

Since the breakdown of the MSM diode in which SiNₓ is used for the current steering layer is caused by heat from current, it has conventionally been considered impossible to pass a current greater than or equal to the breakdown current that is determined by a combination of the electrode material and the nitrogen concentration and the thickness of SiNₓ.

It has also been considered that it is theoretically difficult to increase the breakdown current because current less easily flows and heat from current is more likely to be generated in the MSM diode including SiNₓ where x is large (closer to an insulating film) than in the MSM diode including SiNₓ where x is small.

However, the inventors of the present invention have considered that the thermal breakdown of the MSM diode occurs due to current flowing unevenly in the current steering layer, which accelerates heat in a local region in which current easily flows.

The investigation by the inventors has resulted in discovery that disposing, in the current steering layer of the current steering element, the first metal layer 7 which effectively disperses the heat locally generated by current leads to a significant increase in the breakdown current as compared to the current steering element including a single current steering layer.

The following describes the case of changing the thickness ratio between two current steering layers.

FIG. 3 shows: the current-voltage characteristic of the conventional current steering element which includes a single MSM diode including a current steering layer having SiNₓ where x=0.3 and a thickness of 20 nm; and the current-voltage characteristic of the current steering element 50 according to Embodiment 1 of the present invention which includes (i) the MSM diode 1 including the first current steering layer 6 having SiNₓ where x=0.3 and a thickness of 5 nm and (ii) the MSM diode 2 including the second current steering layer 8 having SiNₓ where x=0.3 and a thickness of 15 nm. As with the above-described current steering element 50 which includes two current steering layers each having Sill, where x=0.3 and a thickness of 10 nm, the breakdown current of the current steering element including the MSM diode 1 and the MSM diode 2, that is, the current steering element including two current steering layers, is significantly higher than that of the current steering element including the single MSM diode. Moreover, it is apparent that the breakdown current is well above the ON current Ion required of the circuit.

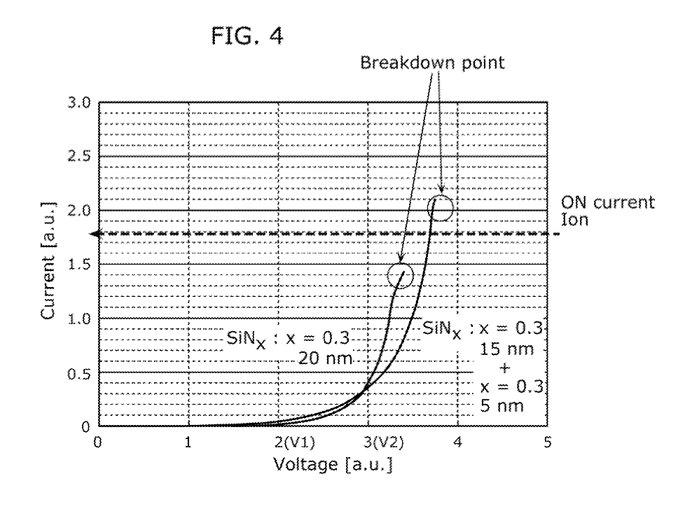

FIG. 4 shows: the current-voltage characteristic of the conventional current steering element which includes the single MSM diode including the current steering layer having SiNₓ where x=0.3 and a thickness of 20 nm; and the current-voltage characteristic of the current steering element 50 according to Embodiment 1 of the present invention which includes (i) the MSM diode 1 including the first current steering layer 6 having SiNₓ where x=0.3 and a thickness of 15 nm and (ii) the MSM diode 2 including the second current steering layer 8 having SiNₓ where x=0.3 and a thickness of 5 nm. As with the above-described current steering element which includes two current steering layers, the breakdown current of the current steering element 50 including the MSM diode 1 and the MSM diode 2, that is, the current steering element 50 including two current steering layers, is significantly higher than that of the current steering element including the single MSM diode. Moreover, it is apparent that the breakdown current is well above the ON current Ion required of the circuit.

As shown in FIG. 2, FIG. 3, and FIG. 4 described above, even when the combination of the thicknesses of the two current steering layers is changed, it is clear that the breakdown current is significantly higher than that of the current steering element which includes the single current steering layer having the same total thickness. In addition, it is also clear that a change in the thickness ratio between the two current steering layers does not significantly alter the characteristics.

It is to be noted that although the above description has shown the case of SiNₓ where x=0.3, the same holds true for the case of SiNₓ where 0<x≦0.85 which can be used as the current steering element which allows large current to flow. Although the advantageous effect has been confirmed in this case based on the result of using SiNₓ for the current steering layers, it is easy to imagine that the same advantageous effect can be achieved even when amorphous Si (silicon) is used for the current steering layers and when the MIM diodes are formed as the current steering layers using an insulator such as an oxide film, because in both cases the heat from the breakdown can be dispersed by the two current steering layers.

Furthermore, different materials may be used for the two current steering layers.

Next, a method for manufacturing the current steering element 50 according to Embodiment 1 of the present invention will be described.

First, the lower electrode 5 is formed on the main surface of a substrate. Here, the condition for forming the lower electrode 5 depends on the material and so on to be used for the electrode. For example, when tantalum nitride (TaN) is used as the material of the lower electrode 5, DC magnetron sputtering is used. Furthermore, a tantalum (Ta) target is sputtered in a mixed atmosphere of argon (Ar) and nitrogen (N) (i.e., by reactive sputtering). Then, the film forming time is adjusted so that the thickness of the lower electrode 5 is in a range of 20 nm to 100 nm inclusive.

Next, a SiNₓ film is formed on the main surface of the lower electrode 5 as the first current steering layer 6. To do so, a polycrystalline silicon target is sputtered by reactive sputtering in a mixed gas atmosphere of Ar and nitrogen, for example. As a typical film forming condition, the pressure is set in a range of 0.08 to 2 Pa inclusive, the substrate temperature is set in a range of 20 to 300 degrees Celsius inclusive, the flow ratio of nitrogen gas (flow ratio of nitrogen in relation to the total flow ratio of Ar and nitrogen) is set in a range of 0 to 40% inclusive, the DC power is set in a range of 100 to 1300 W inclusive, and the film forming time adjusted so that the thickness of the SiNₓ film is in a range of 3 to 30 nm inclusive.

Next, TaN, for example, is formed on the main surface of the first current steering layer 6 as the first metal layer 7. The film forming condition is the same as that for the previously-described lower electrode 5, and thus the description thereof is omitted.

As the first metal layer 7, a material having a high thermal conductivity is preferable. Furthermore, a material which is high in thermal resistance and is less likely to be diffused by heat is preferable for the first metal layer 7. As long as the conductivity is high, the first metal layer 7 may be metal nitride or metal oxide. Thus, the first metal layer 7 may comprise a metal such as Al, Cu, Ti, W, Ir, Cr, Ni, or Nb, or a mixture (alloy) of these metals, which is used for the electrodes of the current steering element.

Alternatively, the first metal layer 7 may comprise: a compound having a conduction property, such as TiN, TiW, TaN, TaSi₂, TaSiN, TiAlN, NbN, WN, WSi₂, WSiN, RuO₂, In₂O₃, SnO₂, or IrO₂; or a mixture of these compounds having a conduction property.

Next, a SiNₓ film is formed on the main surface of the first metal layer 7 as the second current steering layer 8. The film forming condition is the same as that for the previously-described first current steering layer 6, and thus the description thereof is omitted.

Lastly, TaN, for example, is formed on the main surface of the second current steering layer 8 as the upper electrode 13. The film forming condition is the same as that for the previously-described lower electrode 5, and thus the description thereof is omitted.

### Embodiment 2

Embodiment 1 has shown a structure and characteristics of a current steering element including two current steering layers. As described above, the current steering element including two current steering layers can effectively disperse the heat generated by current to the two current steering layers, and thus has a breakdown current which is significantly higher than that of a current steering element including a single current steering layer. Here, a current steering element including multiple current steering layers can also effectively disperse the heat generated by current to each current steering layer, and thus an even higher breakdown current can be expected.

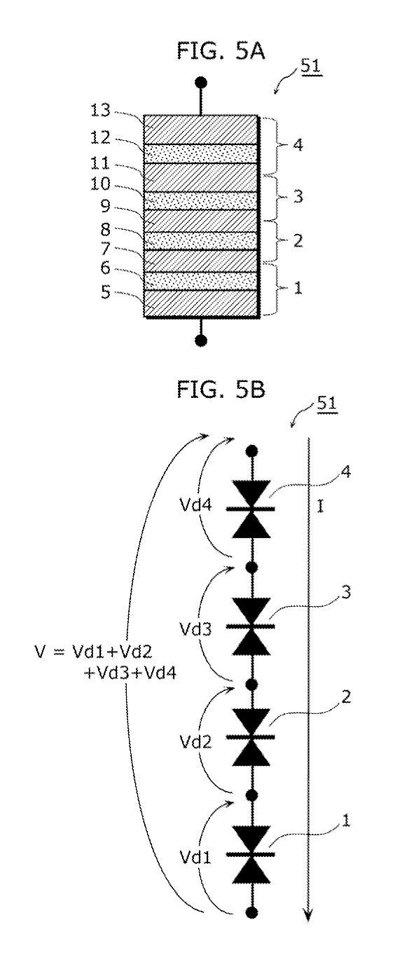

FIG. 5A is a cross-section diagram schematically showing a structure of a current steering element 51 according to Embodiment 2 of the present invention. FIG. 5B is a diagram showing an equivalent circuit of the current steering element 51.

The current steering element 51 includes the MSM diode 1, the MSM diode 2, an MSM diode 3, and an MSM diode 4 connected in series.

Each of the MSM diodes 1 to 4 bidirectionally rectifies current in response to applied voltage, For example, each of the MSM diodes 1 to 4 has the current-voltage characteristic shown in FIG. 10.

The MSM diodes 1 to 4 include the lower electrode 5, the first current steering layer 6, the first metal layer 7, the second current steering layer 8, a second metal layer 9, a third current steering layer 10, a third metal layer 11, a fourth current steering layer 12, and the upper electrode 13 which are stacked in this order.

More specifically, the MSM diode 1 includes the lower electrode 5, the first current steering layer 6, and the first metal layer 7. The MSM diode 2 includes the first metal layer 7, the second current steering layer 8, and the second metal layer 9. The MSM diode 3 includes the second metal layer 9, the third current steering layer 10, and the third metal layer 11. The MSM diode 4 includes the third metal layer 11, the fourth current steering layer 12, and the upper electrode 13. Here, the lower electrode 5 and the upper electrode 13 respectively correspond to the first electrode and the second electrode according to an aspect of the present invention.

A voltage V applied to the MSM diodes 1 to 4 as a whole can be given as V=Vd1+Vd2+Vd3+Vd4, where Vd1 to Vd4 are voltages applied between the respective electrodes of the MSM diodes 1 to 4 and I is current flowing in the MSM diodes 1 to 4.

The current steering element 51 including such four current steering layers can effectively disperse the heat generated by current to each current steering layer, and thus a breakdown current higher than that of the previously-described current steering element including two current steering layers can be expected.

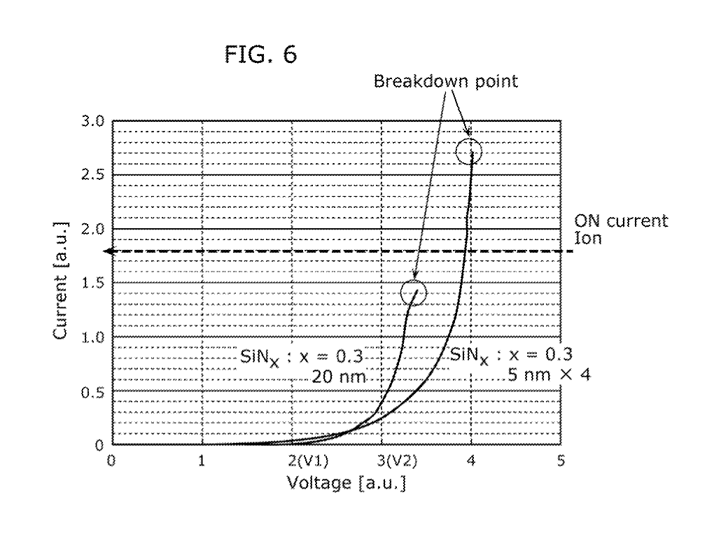

FIG. 6 shows: the current-voltage characteristic of the conventional current steering element which includes the single MSM diode including the current steering layer having SiNₓ where x=0.3 and a thickness of 20 nm; and the current-voltage characteristic of the current steering element 51 according to Embodiment 2 of the present invention which includes the four MSM diodes 1 to 4 each including the current steering layer having SiNₓ where x=0.3 and a thickness of 5 nm. It is to be noted that this current-voltage characteristic diagram shows curves which are drawn by plotting current values while gradually increasing the voltage applied to each current steering element from 0 V until the current steering element (more accurately, the MSM diode(s)) breaks down (i.e., until a breakdown point is reached).

As shown in FIG. 6, the breakdown current of the current steering element 51 including the four current steering layers is significantly higher than that of the conventional current steering element including the single current steering layer. It is to be noted that the total thickness of the four current steering layers included in the current steering element 51 according to Embodiment 2 of the present invention is 20 nm, which is the same as the thickness of the single current steering layer included in the conventional current steering element. Thus, the voltage (threshold voltage) which causes a steep increase in current in the conventional current steering element and the voltage (threshold voltage) which causes a steep increase in current in the current steering element 51 according to Embodiment 2 are substantially equal to each other at V1 as shown in FIG. 6.

It is to be noted that although the above description has shown the examples in which two or four MSM diodes are connected in series, two or more MSM diodes can be connected in series to increase the breakdown current as compared to the case of using a single MSM diode. That is to say, the current steering element according to an aspect of the present invention includes first to Nth bidirectional diodes connected in series where N is an integer greater than or equal to 2. Each of the first to Nth bidirectional diodes includes a first electrode, a second electrode, and a stacked structure which includes layers stacked between the first electrode and the second electrode. The stacked structure includes first to Nth current steering layers and first to (N−1)th metal layers which are alternately stacked.

The larger the number of MSM diodes connected in series is, the more the breakdown current can be increased.

### Embodiment 3

Using the drawings, the fallowing describes in detail, as Embodiment 3 of the present invention, an embodiment of a nonvolatile memory element which includes the above-described current steering element 50 according to Embodiment 1.

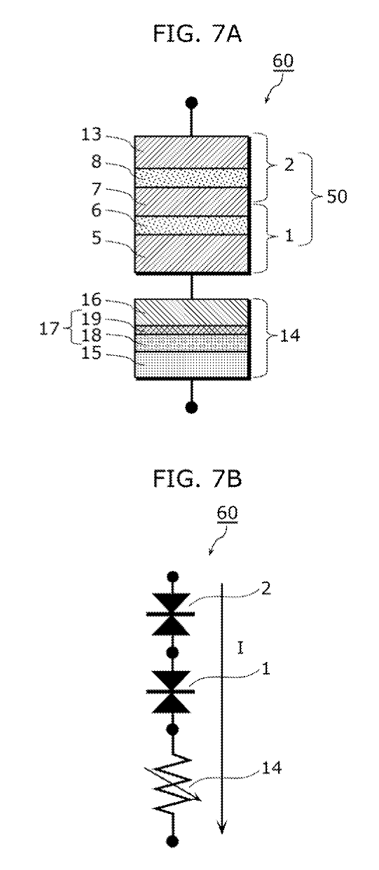

FIG. 7A is a cross-section diagram schematically showing a structure of a nonvolatile memory element 60 according to Embodiment 3 of the present invention. FIG. 7B is a diagram showing an equivalent circuit of the nonvolatile memory element 60. It is to be noted that the structure, dimensions, voltage measuring condition, and so on of the current steering element 50 are the same as those in Embodiment 1, and thus the descriptions thereof will be omitted.

The nonvolatile memory element 60 shown in FIG. 7A and FIG. 7B includes the current steering element 50 and a variable resistance element 14 connected in series. The current steering element 50 is the current steering element 50 described in Embodiment 1 which includes the two current steering layers.

The variable resistance element 14 reversibly changes between a high resistance state and a low resistance state according to the polarity of applied voltage. The variable resistance element 14 includes a lower electrode 15, an upper electrode 16, and a variable resistance layer 17 interposed between the lower electrode 15 and the upper electrode 16.

According to the present embodiment, the variable resistance layer 17 includes an oxygen-deficient Ta oxide layer 18 and a Ta oxide layer 19 higher in oxygen content than the Ta oxide layer 18. The Ta oxide layer 18 and the Ta oxide layer 19 are stacked. The upper electrode 16 comprises iridium (Ir) and the lower electrode 15 comprises tantalum nitride (TaN).

Application of electrical pulses of different polarities on the variable resistance layer 17 reversibly changes the variable resistance layer 17 between a low resistance state and a high resistance state in which the variable resistance layer 1 has different resistance values. This is called bipolar resistance change. Combining the variable resistance layer 17 which performs the bipolar resistance change and the bipolar current steering element 50 forms the nonvolatile memory element 60.

It is to be noted that oxygen-deficient transition metal oxide (preferably, oxygen-deficient tantalum oxide), for example, is used as a material of the variable resistance layer. The oxygen-deficient transition metal oxide refers to oxide which is lower in oxygen content (atomic ratio: the percentage of oxygen atoms relative to the total number of atoms) than oxide having a stoichiometric composition. Normally, the oxide having a stoichiometric composition is an insulator or has a very high resistance value. When the transition metal is tantalum (Ta), for example, the stoichiometric composition of the oxide is Ta₂O₅, and the atomic ratio of O to Ta (O/Ta) is 2.5. Thus, in the case of the oxygen-deficient Ta oxide, the atomic ratio of O to Ta is greater than 0 and smaller than 2.5. In the present embodiment, the oxygen-deficient transition metal oxide is preferably the oxygen-deficient Ta oxide. More preferably, the variable resistance layer at least includes a first tantalum-containing layer having a composition TaOₓ (where 0<x<2.5) and a second tantalum-containing layer having a composition TaO_{y} (where x<y) which are stacked. Other layers, such as a third tantalum-containing layer and another transition metal oxide layer, may be provided as necessary. Here, to enable the variable resistance element to stably operate, it is preferable that TaOₓ satisfy 0.8≦x≦1.9 and TaO_{y} satisfy 2.1≦y≦2.5. The thickness of the second tantalum-containing layer is preferably between 1 nm and 8 nm inclusive.

The variable resistance layer is not limited to the above-described oxygen-deficient tantalum oxide, and other oxygen-deficient transition metal oxide may be used. For example, hafnium oxide or zirconium oxide may be used. When the hafnium oxide is used, the hafnium oxide preferably has a composition HfOₓ where 0.9≦x≦1.6 approximately, whereas when the zirconium oxide is used, the zirconium oxide preferably has a composition ZrOₓ where 0.9≦x≦1.4 approximately. With such composition ranges, the resistance change operation can be stably performed.

Furthermore, an oxygen-deficient oxide film of a transition metal such as nickel (Ni), niobium (Nb), titanium (Ti), zircon (Zr), hafnium (Hf), cobalt (Co), iron (Fe), copper (Cu), or chromium (Cr) may be used for the variable resistance layer. Moreover, aside from Ir, a material such as Pt, Pd, Ag, or Cu may be used for the upper electrode 16 of the variable resistance element 14.

Here, a data write voltage (VM) applied to the nonvolatile memory element 60 is divided into a voltage for the current steering element 50 and a voltage for the variable resistance element 14. Thus, the relationships below are established where VRH is a high resistance writing voltage necessary for changing the variable resistance element 14 to the high resistance state, VRL is a low resistance writing voltage necessary for changing the variable resistance element 14 to the low resistance state, VDH and VDL are voltages for the current steering element 50 obtained by the voltage division, VMH is a high resistance writing voltage applied to the nonvolatile memory element 60 at the time of a high resistance operation, and VML is a low resistance writing voltage applied to the nonvolatile memory element 60 at the time of a low resistance operation.

VMH=VRH+VDH

VML=VRL+VDL

As illustrated in FIG. 10, each of the above-described currents needs to satisfy the relationship below where the ON current of the MSM diode is a current which flows in the MSM diode 1 at the time of the resistance change operation.

“Breakdown current (Ibd) of MSM diode”>“ON current (Ion) of MSM diode”≧“Resistance change current”

Here, the resistance change current is a current necessary for changing the state of the variable resistance element 14 from the high resistance state to the low resistance state (or vice versa). The ON current is a current which flows in the MSM diode at the time of the resistance change operation.

Furthermore, when IRH is the resistance change current necessary for a change to the high resistance state and IRL is the resistance change current necessary for a change to the low resistance state, the current steering element 50 is required to have such performance that allows a current greater than or equal to IRH and IRL to stably flow in response to application of VDH and VDL, respectively, to enable the nonvolatile memory element 60 to stably perform the resistance change operation.

Moreover, it is preferable that the breakdown current of the MSM diode 1 be larger than an initial breakdown current to prevent a breakdown of the MSM diode 1 at the time of initial breakdown. Here, the initial breakdown is a process of changing the variable resistance element 14 from its initial state after being manufactured to a state in which the variable resistance element 14 can reversibly change between the high resistance state and the low resistance state. The initial breakdown current is a current which flows in the variable resistance element 14 at the time of the initial breakdown.

In addition, it is desirable to use the ON region of the MSM diode 1 for the read voltage applied for reading data, so that the read current is less than or equal to VDH and VDL and sufficient.

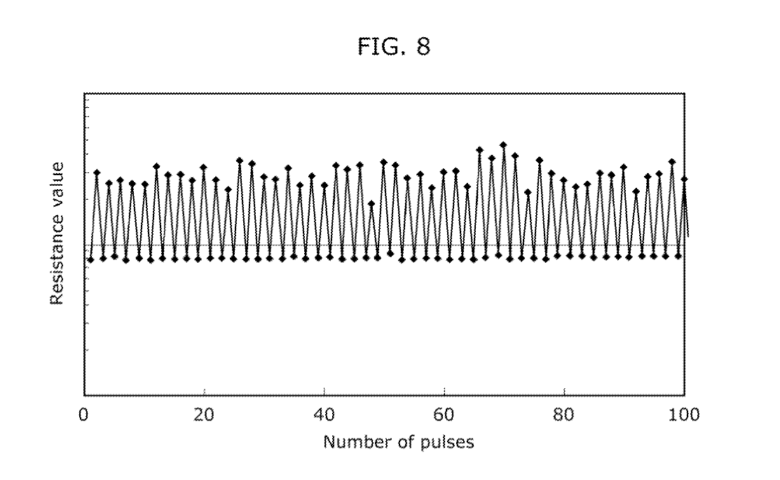

FIG. 8 shows a result of a data write operation of the nonvolatile memory element 60 which includes the MSM diodes 1 and 2 including SiNₓ where x=0.3 under a condition satisfying the above relationships of voltage and current. As shown in FIG. 8, the operation can be stably performed.

It is to be noted that although Embodiment 3 has shown the example in which the current steering element 50 according to Embodiment 1 is used as the current steering element, the current steering element 51 according to Embodiment 2 may be used instead.

### Embodiment 4

In Embodiment 4 of the present invention, a nonvolatile memory device including the above-described nonvolatile memory element 60 will be described.

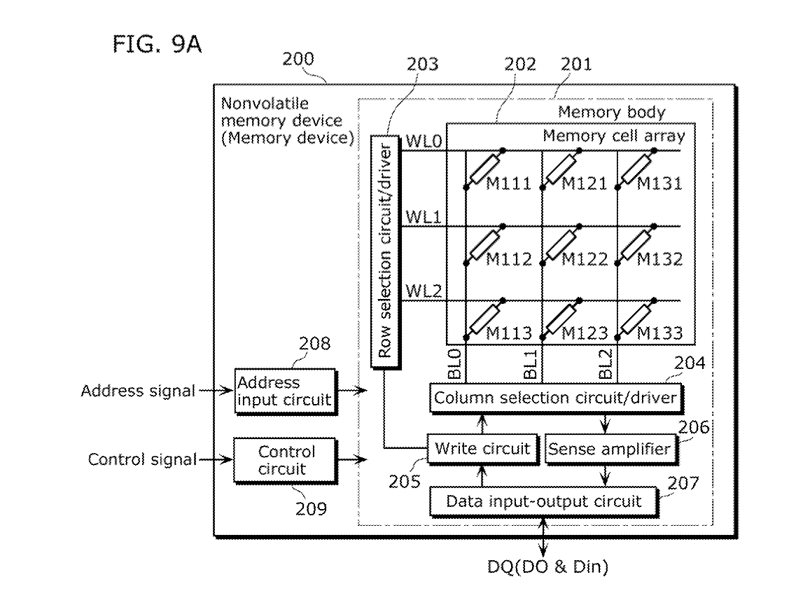

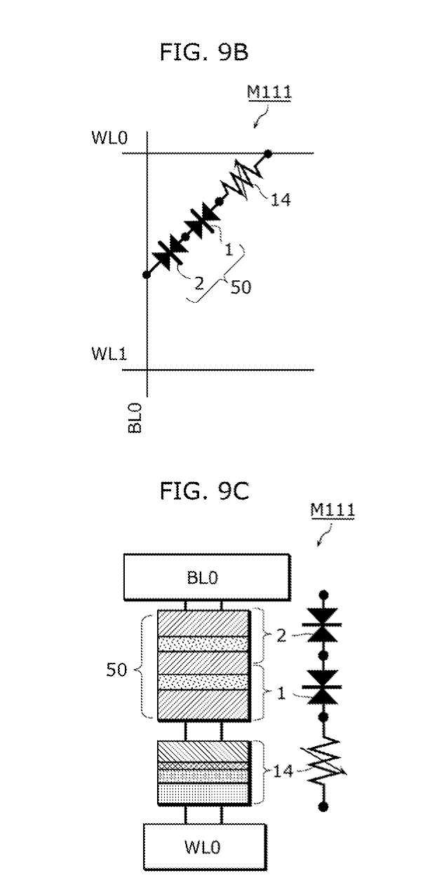

FIG. 9A to FIG. 9C are schematic diagrams showing a structure of a nonvolatile memory device (hereinafter also simply referred to as “memory device”) 200 according to Embodiment 3 of the present invention which includes a plurality of nonvolatile memory elements.

FIG. 9A is a schematic diagram showing a structure of the memory device 200 as viewed from the surface of a semiconductor chip. FIG. 9B is a schematic diagram of an enlarged memory cell M111 shown in FIG. 9A. FIG. 9C is a cross-section diagram of the memory cell M111.

The memory device 200 shown in FIG. 9A is a cross-point memory device in which memory cells are disposed at points where word lines and bit lines stereoscopically intersect. The memory device 200 includes a memory cell array 202 in which a plurality of the nonvolatile memory elements 60 (e.g., 256 nonvolatile memory elements 60) having the structure described in Embodiment 3 (FIG. 7B) are arranged as memory cells. It is to be noted that FIG. 9A only shows three rows and three columns of memory cells for simplicity.

The memory device 200 includes a memory body 201. The memory body 201 includes the memory cell array 202, a row selection circuit/driver 203, a column selection circuit/driver 204, a write circuit 205 for writing information, a sense amplifier 206 which amplifies a potential of a bit line, and a data input-output circuit 207 which receives and outputs input and output data via a terminal DQ.

The memory device 200 further includes an address input circuit 208 which receives an address signal from outside and a control circuit 209 which controls the operation of the memory body 201 based on a control signal received from outside.

In the memory cell array 202, the nonvolatile memory elements 60 described in Embodiment 3 are arranged in a matrix (in a two-dimensional manner) as memory cells. The memory cell array 202 includes a plurality of word lines WL0, WL1, and WL2 and a plurality of bit lines BL0, BL1, and BL2. The word lines WL0, WL1, and WL2 are formed in parallel above a semiconductor substrate. The bit lines BL0, BL1, and BL2 are formed in parallel above the word lines WL0, WL1, and WL2, in a plane parallel to the main surface of the semiconductor substrate. The bit lines BL0, BL1, and BL2 stereoscopically cross the word lines WL0, WL1, and WL2.

In the memory cell array 202, a plurality of nonvolatile memory elements M111, M112, M113, M121, M122, M123, M131, M132, and M133 (hereinafter simply referred to as “memory elements M111, M112 . . . ”) are disposed in a matrix so as to correspond to the stereoscopic cross-points of the word lines WL0, WL1, and WL2 and the bit lines BL0, BL1, and BL2.

Here, each of the memory elements M111, M112 . . . corresponds to the nonvolatile memory element 60 according to Embodiment 3. Each of the memory elements M111, M112 . . . includes the variable resistance element 14 and the current steering element 50 which is connected to and on the variable resistance element 14. The variable resistance element 14 is formed above the semiconductor substrate, and includes a variable resistance layer including tantalum oxide.

The address input circuit 208 receives an address signal from an external circuit (not shown) and generates a row address signal and a column address signal based on the address signal. Furthermore, the address input circuit 208 outputs the row address signal to the row selection circuit/driver 203 and the column address signal to the column selection circuit/driver 204. Here, the address signal is a signal indicating the address of a particular memory element selected from among the memory elements M111, M112 . . . . The row address signal is a signal indicating a row address included in the address indicated by the address signal. The column address signal is a signal indicating a column address included in the address indicated by the address signal.

In the information write cycle, the control circuit 209 generates, according to input data Din received by the data input-output circuit 207, a write signal which instructs application of a write voltage. The control circuit 209 outputs the write signal to the write circuit 205. In the information read cycle, the control circuit 209 generates a read signal which instructs application of a read voltage. The control circuit 209 outputs the read signal to the column selection circuit/driver 204.

The row selection circuit/driver 203 receives the row address signal from the address input circuit 208 and selects one of the word lines WL0, WL1, and WL2 according to the row address signal. The row selection circuit/driver 203 then applies a predetermined voltage to the selected word line.

The column selection circuit/driver 204 receives the column address signal from the address input circuit 208 and selects one of the bit lines BL0, BL1, and BL2 according to the column address signal. The column selection circuit/driver 204 then applies a write voltage or a read voltage to the selected bit line.

The row selection circuit/driver 203 and the column selection circuit/driver 204 function as a selection circuit which selects at least one memory cell from the memory cell array 202.

The write circuit 205, in the case of receiving the write signal from the control circuit 209, outputs to the row selection circuit/driver 203 a signal instructing application of voltage on the selected word line, and outputs to the column selection circuit/driver 204 a signal instructing application of a write voltage on the selected bit line. More specifically, the write circuit 205 applies a predetermined voltage (greater than or equal to VMH and VML described in Embodiment 3) to the memory cell selected by the selection circuit (the row selection circuit/driver 203 and the column selection circuit/driver 204), to change the variable resistance element 14 included in the selected memory cell from one of the high resistance state and the low resistance state to the other.

In the information read cycle, the sense amplifier 206 amplifies a potential of a bit line which is subject to the read operation. Resultant output data DO is outputted to an external circuit via the data input-output circuit 207. More specifically, the sense amplifier 206 determines whether the variable resistance element 14 included in the memory cell selected by the selection circuit (the row selection circuit/driver 203 and the column selection circuit/driver 204) is in the high resistance state or the low resistance state.

Thus, the write to and read from the memory elements M111, M112 . . . in each of which the current steering element 50 and the variable resistance element 14 are connected in series are performed in the same manner as in Embodiment 3. More specifically, at the time of the write operation, the current steering element 50 is in the ON state in which high voltage is applied. This leads to efficient application of high voltage on the variable resistance element 14, allowing the write operation to be stably performed on the memory elements M111, M112 . . . .

At the time of the read operation, the current steering element 50 is in the OFF state in which low voltage is applied. This leads to application of only relatively low voltage on the variable resistance element 14, efficiently preventing write disturb. Moreover, the current steering element 50 can efficiently prevent the variable resistance element 14 from being adversely affected by noise and crosstalk. This prevents misoperation of the memory elements M111, M112 . . . .

As described above, the memory device 200 according to Embodiment 4 of the present invention includes the nonvolatile memory elements 60 described in Embodiment 3 of the present invention. More specifically, for the memory device 200, the current steering element 50 can be used which: bidirectionally rectifies current in response to applied voltage; has a margin with respect to a write voltage which is applied to write in a memory cell; and allows large current to stably flow. This enables the memory device 200 to perform the bidirectional operation and stably operate without write disturb caused by sneak current from an adjacent memory cell nor without being adversely affected by noise or crosstalk. This shows that the memory device 200 with high reliability can be manufactured.

The initial breakdown operation may be performed by the memory device 200, or may be partially or entirely performed by an external device (e.g., a tester). For example, the initial breakdown voltage may be generated in the memory device 200 or supplied to the memory device 200 from an external device.

The current steering element, the nonvolatile memory element, and the nonvolatile memory device according to embodiments of the present invention have been described thus far; however, the present invention is not limited to these embodiments.

Each of the current steering element, the nonvolatile memory element, and the nonvolatile memory device according to the above embodiments is typically implemented in the form of an LSI that is an integrated circuit. These LSIs may be manufactured as individual chips, or some or all of the LSIs may be integrated into one chip.

Furthermore, the means for circuit integration is not limited to the LSI, and implementation with a dedicated circuit or a general-purpose processor is also available. It is also acceptable to use: a field programmable gate array (FPGA) that is programmable after the LSI has been manufactured; and a reconfigurable processor in which connections and settings of circuit cells within the LSI are reconfigurable.

Moreover, although the above-described cross-section diagrams and so on show each structural element in such a manner that each structural element has linear corners and linear sides, the present invention also includes structural elements having round corners and curved sides due to manufacturing reasons.

The current steering element, the nonvolatile memory element, and the nonvolatile memory device according to Embodiments 1 to 4 and their variations are not limited to the structures described in each embodiment or variation alone, and a combination of these embodiments and variations is also possible.

The numerical values used above are all exemplary values used for describing a concrete example of the present invention, and the present invention is not limited to the exemplary numerical values. Furthermore, the materials of the structural elements described above are all exemplary materials used for describing a concrete example of the present invention, and the present invention is not limited to the exemplary materials. Moreover, the connections between the structural elements are exemplary connections used for describing a concrete example of the present invention, and the connection which achieves the functions of the present invention is not limited to the exemplary connections.

The manner in which the functional blocks are divided in the block diagram is a mere example. A plurality of functional blocks may be implemented as one functional block; one functional block may be divided into a plurality of functional blocks; or part of the functions may be implemented by another functional block. Furthermore, the functions of a plurality of functional blocks having similar functions may be processed in parallel or by time division by single hardware or software.

Furthermore, those skilled in the art will readily appreciate that various modifications may be made in the above embodiments without materially departing from the scope of the present invention. Accordingly, all such modifications are included in the present invention.

### INDUSTRIAL APPLICABILITY

The present invention is applicable to current steering elements, nonvolatile memory elements, and nonvolatile memory devices. Furthermore, the present invention is useful as nonvolatile memory devices used in various electronic devices such as personal computers and mobile phones.

### REFERENCE SIGNS LIST

1, 2, 3, 4 MSM diode
5 Lower electrode
6 First current steering layer
7 First metal layer
8 Second current steering layer
9 Second metal layer
10 Third current steering layer
11 Third metal layer
12 Fourth current steering layer
13 Upper electrode
14 Variable resistance element
15 Lower electrode
16 Upper electrode
17 Variable resistance layer
18, 19 Ta oxide layer
50, 51 Current steering element
60 Nonvolatile memory element
101 MSM diode
102 Lower electrode
103 Upper electrode
104 Current steering layer
200 Nonvolatile memory device (memory device)
201 Memory body
202 Memory cell array
203 Row selection circuit/driver
204 Column selection circuit/driver
205 Write circuit
206 Sense amplifier
207 Data input-output circuit
208 Address input circuit
209 Control circuit

1. A nonvolatile memory element comprising:
a current steering element which bidirectionally rectifies current in response to applied voltage; and
a variable resistance element which is connected in series with the current steering element and reversibly changes between a high resistance state and a low resistance state according to a polarity of applied voltage,
wherein the current steering element includes a first bidirectional diode and a second bidirectional diode which are connected in series and each of which bidirectionally rectifies current in response to applied voltage,
the first bidirectional diode and the second bidirectional diode include a first electrode, a first current steering layer, a first metal layer, a second current steering layer, and a second electrode which are stacked in this order, and
the current steering element has a breakdown current which is larger than an initial breakdown current which flows in the variable resistance element at a time of initial breakdown which changes the variable resistance element from an initial state to a state in which the variable resistance element can reversibly change between the high resistance state and the low resistance state, the initial state being a state of the variable resistance element after being manufactured.

2. The nonvolatile memory element according to claim 1,
wherein at least one of the first current steering layer and the second current steering layer is a semiconductor layer.

3. The volatile memory element according to claim 2,
wherein the semiconductor layer comprises SiNₓ where 0<x≦0.85.

4. The nonvolatile memory element according to claim 2,
wherein the semiconductor layer comprises silicon.

5. The nonvolatile memory element according to claim 1,
wherein at least one of the first current steering layer and the second current steering layer is an insulator.

6. The nonvolatile memory element according to claim 1,
wherein the current steering element includes
first to Nth bidirectional diodes connected in series and including the first bidirectional diode and the second bidirectional diode, where N is an integer greater than or equal to 3,
the first to Nth bidirectional diodes include:
the first electrode;
the second electrode; and
a stacked structure which includes layers stacked between the first electrode and the second electrode, and
the stacked structure includes first to Nth current steering layers and first to (N−1)th metal layers which are alternately stacked.

7. The nonvolatile memory element according to claim 1,
wherein the variable resistance element includes:
a third electrode;
a fourth electrode; and
an oxygen-deficient transition metal oxide layer interposed between the third electrode and the fourth electrode.

8. The nonvolatile memory element according to claim 7,
wherein the transition metal oxide layer includes a first transition metal oxide layer and a second transition metal oxide layer which are stacked, the second transition metal oxide layer being different from the first transition metal oxide layer in degree of oxygen deficiency.

9. A nonvolatile memory device comprising:
a memory cell array in which a plurality of the nonvolatile memory elements according to claim 1 are two-dimensionally arranged;
a selection circuit which selects at least one of the nonvolatile memory elements from the memory cell array;
a write circuit which applies voltage on the nonvolatile memory element selected by the selection circuit, to change a variable resistance element included in the selected nonvolatile memory element from one of a high resistance state and a low resistance state to the other; and
a sense amplifier which determines whether the variable resistance element included in the nonvolatile memory element selected by the selection circuit is in the high resistance state or the low resistance state.

10. A method of manufacturing a nonvolatile memory element, comprising:
forming a current steering element which bidirectionally rectifies current in response to applied voltage; and
forming a variable resistance element which is connected in series with the current steering element and reversibly changes between a high resistance state and a low resistance state according to a polarity of applied voltage,
wherein the forming of a current steering element includes:
forming a first electrode on a semiconductor substrate;
forming a first current steering layer on the first electrode;
forming a first metal layer on the first current steering layer;
forming a second current steering layer on the first metal layer; and
forming a second electrode on the second current steering layer,
the first electrode, the first current steering layer, the first metal layer, the second current steering layer, and the second electrode are included in a first bidirectional diode and a second bidirectional diode which are connected in series and each of which bidirectionally rectifies current in response to applied voltage, and
the current steering element has a breakdown current which is larger than an initial breakdown current which flows in the variable resistance element at a time of initial breakdown which changes the variable resistance element from an initial state to a state in which the variable resistance element can reversibly change between the high resistance state and the low resistance state, the initial state being a state of the variable resistance element after being manufactured.

11. A method of initial breakdown of a nonvolatile memory element,
the nonvolatile memory element including:
a current steering element which bidirectionally rectifies current in response to applied voltage; and
a variable resistance element which is connected in series with the current steering element and reversibly changes between a high resistance state and a low resistance state according to a polarity of applied voltage,
the current steering element including a first bidirectional diode and a second bidirectional diode which are connected in series and each of which bidirectionally rectifies current in response to applied voltage, the first bidirectional diode and the second bidirectional diode including a first electrode, a first current steering layer, a first metal layer, a second current steering layer, and a second electrode which are stacked in this order, and
the method of initial breakdown comprising
performing initial breakdown to change the variable resistance element from an initial state to a state in which the variable resistance element can reversibly change between the high resistance state and the low resistance state, the initial state being a state of the variable resistance element after being manufactured,
wherein the current steering element has a breakdown current which is larger than an initial breakdown current which flows in the variable resistance element at a time of the initial breakdown.
